(19) United States
(12) Patent Application Publication
(10) Pub. No.: US 2018/0277631 A1
(43) Pub. Date: Sep. 27, 2018

(54) SEMICONDUCTOR DEVICE AND METHOD FOR MANUFACTURING SAME

(71) Applicant: Toshiba Memory Corporation, Minato-ku (JP)

(72) Inventor: Yusuke OKUMURA, Yokkaichi (JP)

(73) Assignee: Toshiba Memory Corporation, Minato-ku (JP)

(21) Appl. No.: 15/705,438

(22) Filed: Sep. 15, 2017

(30) Foreign Application Priority Data
Mar. 24, 2017 (JP) 2017-059911

(51) Int. Cl. H01L 29/10; H01L 27/11582; H01L 27/11556; H01L 21/311

(52) U.S. Cl. CPC H01L 29/1037; H01L 21/31116; H01L 27/11556; H01L 27/11582

(57) ABSTRACT

According to one embodiment, the joint part has a diameter larger than a diameter of the first columnar part and a diameter of the second columnar part. The joint part includes an intermediate semiconductor body continuous with the first semiconductor body and the second semiconductor body. A central axis of the second columnar part is shifted in a first direction along a surface of the foundation layer with respect to a central axis of the first columnar part. A width along the first direction from the central axis of the first columnar part in an upper end of the first columnar part is larger than a width along a second direction opposite to the first direction from the central axis of the first columnar part in the upper end of the first columnar part.

### CROSS-REFERENCE TO RELATED APPLICATION

This application is based upon and claims the benefit of priority from Japanese Patent Application No. 2017-059911, filed on Mar. 24, 2017; the entire contents of which are incorporated herein by reference.

### FIELD

Embodiments described herein relate generally to a semiconductor device and a method for manufacturing a semiconductor device.

### BACKGROUND

A three-dimensional memory has been proposed. The three-dimensional memory has a stacked body including a plurality of electrode layers stacked with insulating layers interposed, and columnar portions extending in the stacked body in the stacking direction. A process of forming the columnar portions includes a process of forming holes to the stacked body, and a process of forming a charge storage film and a semiconductor body in the holes.

Further, there is also made a proposal of dividing the formation of the stacked body and the formation of the holes into two or more times. A first hole is formed to a lower layer side of the stacked body, then an upper layer side of the stacked body is stacked on the lower layer side of the stacked body, and then a second hole is formed to the upper layer side of the stacked body.

### BRIEF DESCRIPTION OF THE DRAWINGS

FIG. 1 is a schematic perspective view of a semiconductor device of an embodiment;

FIG. 2 is a schematic cross-sectional view of the semiconductor device of the embodiment;

FIG. 3A is a schematic enlarged cross-sectional view of a part of a second stacked part of the semiconductor device of the embodiment, and FIG. 3B is a schematic enlarged cross-sectional view of a part of a first stacked part of the semiconductor device of the embodiment;

FIG. 4 to FIG. 23 are schematic cross-sectional views showing a method for manufacturing the semiconductor device of the embodiment; and

FIG. 24 is a schematic perspective view of a semiconductor device of the embodiment.

### DETAILED DESCRIPTION

According to one embodiment, a semiconductor device includes a foundation layer, a first stacked part, a first columnar part, a second stacked part, a second columnar part, an intermediate layer, and a joint part. The first stacked part is provided on the foundation layer. The first stacked part includes a plurality of first electrode layers stacked with first insulators interposed. The first columnar part includes a first semiconductor body extending in the first stacked part in a stacking direction of the first stacked part, and a first charge storage part provided between the first semiconductor body and one of the first electrode layers. The second stacked part is provided on the first stacked part. The second stacked part includes a plurality of second electrode layers stacked with second insulators interposed. The second columnar part includes a second semiconductor body extending in the second stacked part in a stacking direction of the second stacked part, and a second charge storage part provided between the second semiconductor body and one of the second electrode layers. The intermediate layer is provided between the first stacked part and the second stacked part. The joint part is provided between the first columnar part and the second columnar part in the intermediate layer. The joint part has a diameter larger than a diameter of the first columnar part and a diameter of the second columnar part. The joint part includes an intermediate semiconductor body continuous with the first semiconductor body and the second semiconductor body. A central axis of the second columnar part is shifted in a first direction along a surface of the foundation layer with respect to a central axis of the first columnar part. A width along the first direction from the central axis of the first columnar part in an upper end of the first columnar part is larger than a width along a second direction opposite to the first direction from the central axis of the first columnar part in the upper end of the first columnar part.

The embodiment will hereinafter be described with reference to the drawings. It should be noted that in the drawings, the same elements are denoted by the same reference symbols.

In the embodiment, as the semiconductor device, a semiconductor storage device having a memory cell array with a three-dimensional structure will be described, for example.

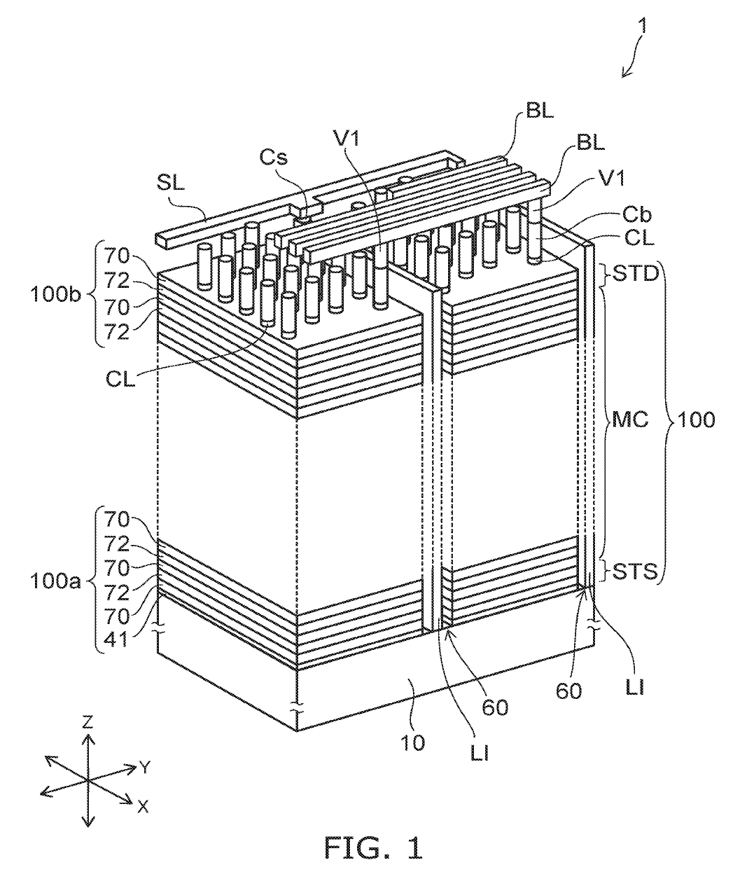

FIG. 1 is a schematic perspective view of the memory cell array 1 according to the embodiment.

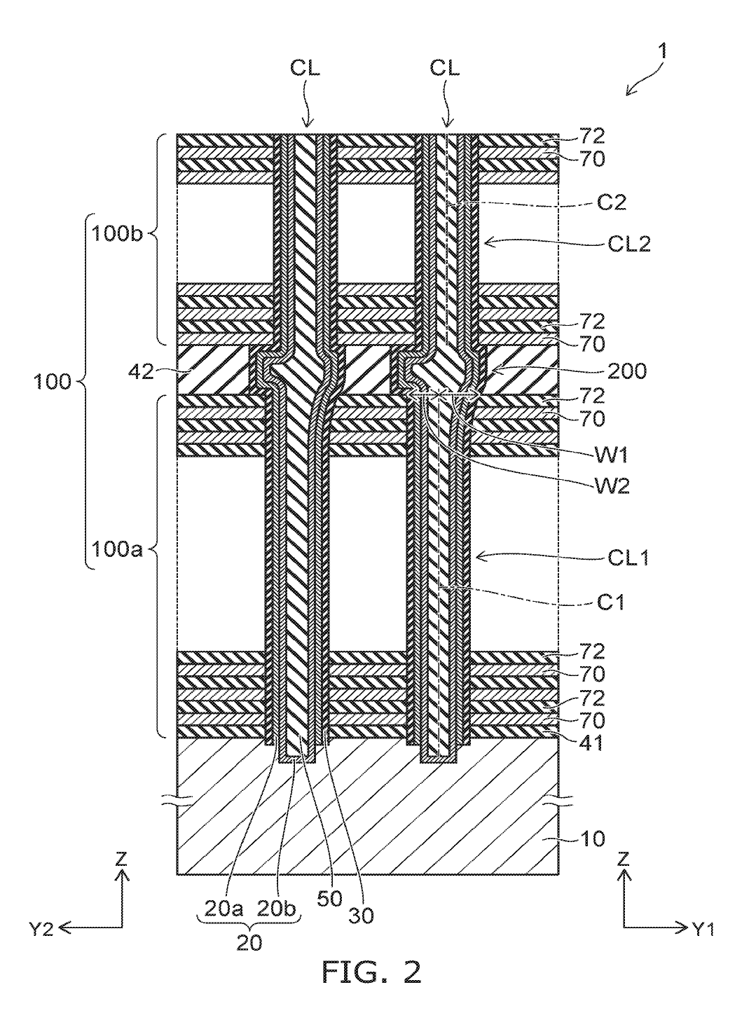

FIG. 2 is a schematic cross-sectional view of the memory cell array 1.

In FIG. 1, two directions parallel to a principal surface of a substrate 10 and perpendicular to each other are defined as an X-direction and a Y-direction, and a direction perpendicular to both of the X-direction and the Y-direction is defined as a Z-direction (stacking direction).

The Y-direction is further classified into a Y1-direction and a Y2-direction opposite to the Y1-direction in the cross-section shown in FIG. 2. The Y1-direction represents a displacement direction of the second columnar part CL2 with respect to the first columnar direction CL1.

The memory cell array 1 has the substrate 10 as a foundation layer, a stacked body 100 provided on the substrate 10, a plurality of columnar portions CL, a plurality of separation portions 60, and upper layer interconnection provided above the stacked body 100. FIG. 1 shows, for example, bit lines BL and a source layer SL as the upper layer interconnection.

The columnar portions CL are each formed to have a roughly cylindrical shape extending through the stacked body 100 in the stacking direction (the Z-direction) of the stacked body 100. The plurality of columnar portions CL is arranged in, for example, a staggered arrangement. Alternatively, the plurality of columnar portions CL can also be arranged in a square lattice along the X-direction and the Y-direction.

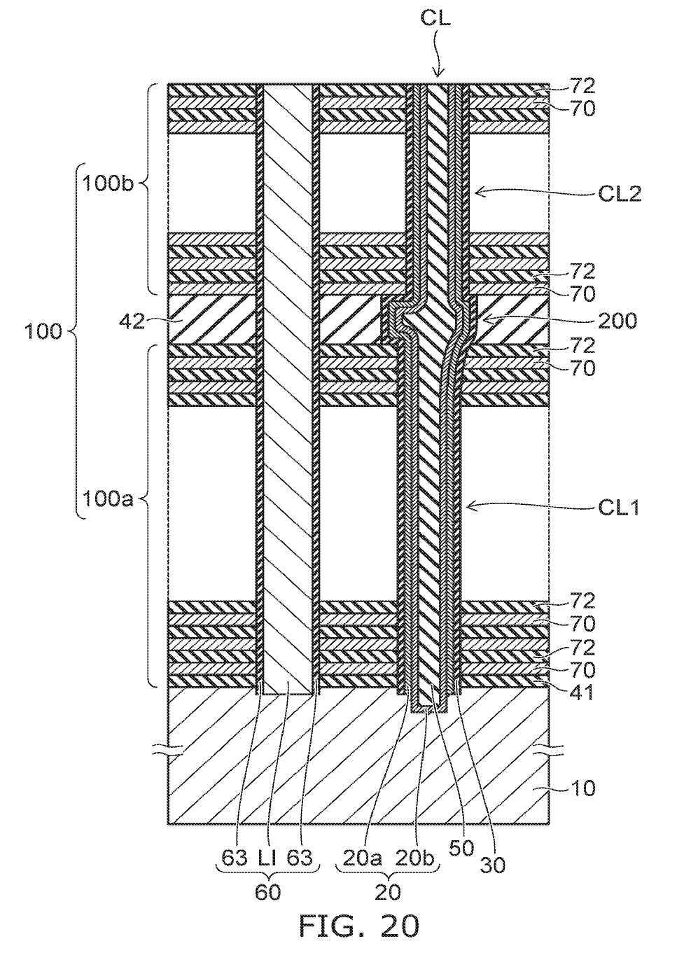

The separation portions 60 separate the stacked body 100 into a plurality of blocks (or finger sections) in the Y-direction. The separation portions 60 each have an interconnect portion LI extending in the X-direction and the Z-direction. As shown in FIG. 20, insulating films 63 are provided between the interconnect portion LI and the stacked body 100.

The plurality of bit lines BL is provided above the stacked body 100. The bit lines BL are each, for example, a metal film extending in the Y-direction. The bit lines BL are separated from each other in the X-direction.

The upper end part of a semiconductor body 20 described later of the columnar portion CL is connected to the bit line BL via a contact Cb and a contact V1 shown in FIG. 1.

The plurality of columnar portions CL is connected to one of the bit lines BL common to the plurality of columnar portions CL. The plurality of columnar portions CL connected to the common bit line BL includes the columnar portions CL each selected from corresponding one of the blocks separated by the separation portions 60 from each other in the Y-direction.

As shown in FIG. 2, the stacked body 100 has a first stacked part 100a provided on the substrate 10, a second stacked part 100b provided on the first stacked part 100a, and an intermediate layer 42 provided between the first stacked part 100a and the second stacked part 100b.

The first stacked part 100a has a plurality of electrode layers 70. The electrode layers 70 are stacked in a direction (the Z-direction) perpendicular to the principal surface of the substrate 10 with insulating layers (insulators) 72 interposed.

Similarly to the first stacked part 100a, the second stacked part 100b also has a plurality of electrode layers 70 stacked in the Z-direction with the insulating layers 72 interposed.

The electrode layers 70 are each, for example, a metal layer. The electrode layers 70 are each, for example, a tungsten layer including tungsten as a major component or a molybdenum layer including molybdenum as a major component. The insulating layers 72 are each a silicon oxide layer including, for example, a silicon oxide as a major component.

The intermediate layer 42 is, for example, a silicon oxide layer including a silicon oxide as a major component similarly to the insulating layer 72. The thickness of the intermediate layer 42 is thicker than the thickness of one of the electrode layers 70 and the thickness of one of the insulating layers 72.

The substrate 10 is, for example, a silicon substrate. An active region (a semiconductor region) doped with impurities and having an electrically conductive property is provided at a surface the substrate 10. An insulating layer 41 is provided on the surface of the active region. A lowermost one of the electrode layers 70 of the first stacked part 100a is provided on the insulating layer 41.

The columnar portions CL each have the first columnar part CL1 formed in the first stacked part 100a, the second columnar part CL2 formed in the second stacked part 100b, and a joint part 200 connecting the first columnar part CL1 and the second columnar part CL2.

The first columnar part CL1 extends through the first stacked part 100a in the stacked direction (the Z-direction), and the second columnar part CL2 extends through the second stacked part 100b in the stacking direction. The joint part 200 is provided between the first columnar part CL1 and the second columnar part CL2 in the intermediate layer 42, and is continuous with the first columnar part CL1 and the second columnar part CL2.

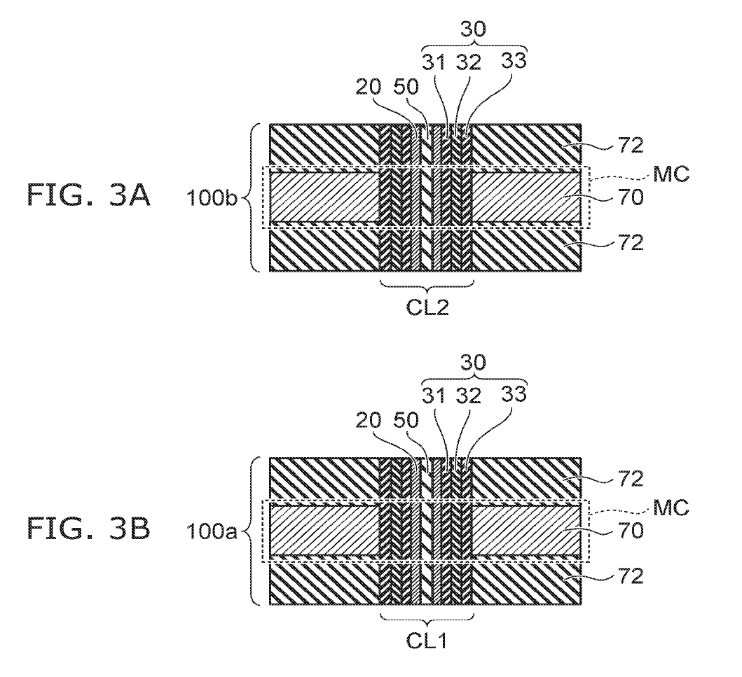

FIG. 3A is a schematic enlarged cross-sectional view of a part of the second stacked part 100b and the second columnar part CL2.

FIG. 3B is a schematic enlarged cross-sectional view of a part of the first stacked part 100a and the first columnar part CL1.

The first columnar part CL1 has a memory film 30, the semiconductor body 20, and a core film 50 having an insulating property. Similarly to the first columnar part CL1, the second columnar part CL2 has the memory film 30, the semiconductor body 20, and the core film 50 having an insulating property.

As shown in FIG. 2, the joint part 200 is also provided with the semiconductor body 20, and the semiconductor body 20 provided to the joint part 200 is continuous with the semiconductor body 20 of the second columnar part CL2 and the semiconductor body 20 of the first columnar part CL1.

The semiconductor body 20 extends through the second stacked part 100b, the joint part 200, and the first stacked part 100a in the stacking direction (the Z-direction) continuously like a pipe.

The upper end part of the semiconductor body 20 is connected to the bit line BL via the contact Cb and the contact V1 shown in FIG. 1. The lower end part of the semiconductor body 20 has contact with a surface part (an active region) of the substrate 10 as shown in FIG. 2.

Further, as shown in FIG. 20, the lower end of the interconnect portion LI has contact with the surface part (the active region) of the substrate 10.

The memory film 30 is provided between the electrode layers 70 and the semiconductor body 20 to surround the semiconductor body 20 from the outer peripheral side. The core film 50 is provided inside the semiconductor body 20 shaped like a pipe.

The joint part 200 is also provided with the memory film 30, and the memory film 30 provided to the joint part 200 is continuous with the memory film 30 of the second columnar part CL2 and the memory film 30 of the first columnar part CL1.

The memory film 30 extends continuously through the second stacked part 100b, the joint part 200, and the first stacked part 100a in the stacking direction (the Z-direction).

As shown in FIGS. 3A and 3B, the memory 30 is a stacked film having a tunnel insulating film 31, a charge storage film (a charge storage section) 32, and a block insulating film 33.

The tunnel insulating film 31 is provided between the semiconductor body 20 and the charge storage film 32. The charge storage film 32 is provided between the tunnel insulating film 31 and the block insulating film 33. The block insulating film 33 is provided between the charge storage film 32 and the electrode layer 70.

The semiconductor body 20, the memory film 30, and the electrode layer 70 constitute a memory cell MC. The memory cell MC has a vertical transistor structure in which the electrode layer 70 surrounds the periphery of the semiconductor body 20 via the memory film 30.

The first stacked part 100a and the second stacked part 100b are each provided with a plurality of memory cells MC. The intermediate layer 42 is not provided with the memory cell.

In the memory cell MC having the vertical transistor structure, the semiconductor body 20 is, for example, a channel body made of silicon, and the electrode layer 70 functions as a control gate. The charge storage film 32 functions as a data storage layer for storing the charge injected from the semiconductor body 20.

The semiconductor storage device according to the embodiment is a nonvolatile semiconductor storage device capable of electrically and freely performing data erasure and data writing, and holding the storage contents even if the power is cut.

The memory cell MC is, for example, a charge-trapping memory cell. The charge storage film 32 has a number of trap sites for capturing the charge in the film having an insulating property, and includes, for example, a silicon nitride film. Alternatively, the charge storage film 32 can also be a floating gate having an electrically conductive property surrounded by an insulator.

The tunnel insulating film 31 acts as a potential barrier when the charge is injected from the semiconductor body 20 to the charge storage film 32, or when the charge stored in the charge storage film 32 is emitted to the semiconductor body 20. The tunnel insulating film 31 includes, for example, a silicon oxide film.

The block insulating film 33 prevents the charge stored in the charge storage film 32 from being emitted to the electrode layer 70. Further, the block insulating film 33 prevents back tunneling of the charge from the electrode layer 70 to the columnar parts CL1, CL2.

The block insulating film 33 includes, for example, a silicon oxide film. Further, the block insulating film 33 can also have a stacked structure of the silicon oxide film and a metal oxide film. In this case, the silicon oxide film is provided between the charge storage film 32 and the metal oxide film, and the metal oxide film can be provided between the silicon oxide film and the electrode layer 70. As the metal oxide film, there can be cited, for example, an aluminum oxide film, a zirconium oxide film and a hafnium oxide film.

As shown in FIG. 1, an upper layer part of the second stacked part 100b is provided with a drain-side selection transistor STD. A lower layer part of the first stacked part 100a is provided with a source-side selection transistor STS.

At least uppermost one of the electrode layers 70 of the second stacked part 100b functions as a control gate of the drain-side selection transistor STD. At least lowermost one of the electrode layers 70 of the first stacked part 100a functions as a control gate of the source-side selection transistor STS.

A plurality of memory cells MC is provided between the drain-side selection transistor STD and the source-side selection transistor STS. The plurality of memory cells MC, the drain-side selection transistor STD, and the source-side selection transistor STS are connected in series to each other via the semiconductor body 20 of the columnar portion CL to constitute one memory string. The memory strings are arranged in directions of a plane parallel to the X-Y plane in, for example, a zigzag manner, and thus, the plurality of memory cells MC is three-dimensionally provided in the X-direction, Y-direction, and the Z-direction.

The diameter of the joint part 200 is larger than the diameter of the first columnar part CL1 and the diameter of the second columnar part CL2. Further, in the cross-section shown in FIG. 2, the central axis C2 of the second columnar part CL2 is shifted in the Y1-direction along the surface of the substrate 10 with respect to the central axis C1 of the first columnar part CL1.

The width W1 along the Y1-direction from the central axis C1 of the first columnar part CL1 in the upper end of the first columnar part CL1 is larger than the width W2 along the Y2-direction opposite to the Y1-direction from the central axis C1 of the first columnar part CL1 in the upper end of the first columnar part CL1.

The step between the sidewall on the Y1-direction side of the joint part 200 and the sidewall on the Y1-direction side of the first columnar part CL1 is smaller than the step between the sidewall on the Y2-direction side of the joint part 200 and the sidewall on the Y2-direction side of the first columnar part CL1.

The sidewall on the Y1-direction side of the joint part 200 and the sidewall on the Y1-direction side of the first columnar part CL1 are more gently connected than the connection between the sidewall on the Y2-direction side of the joint part 200 and the sidewall on the Y2-direction side of the first columnar part CL1.

The displacement (an amount of projection) toward the Y2-direction of the sidewall on the Y2-direction side of the joint part 200 from the sidewall on the Y2-direction side of the second columnar part CL2 is larger than the displacement (an amount of projection) toward the Y2-direction of the sidewall on the Y2-direction side of the joint part 200 from the sidewall on the Y2-direction side of the first columnar part CL1.

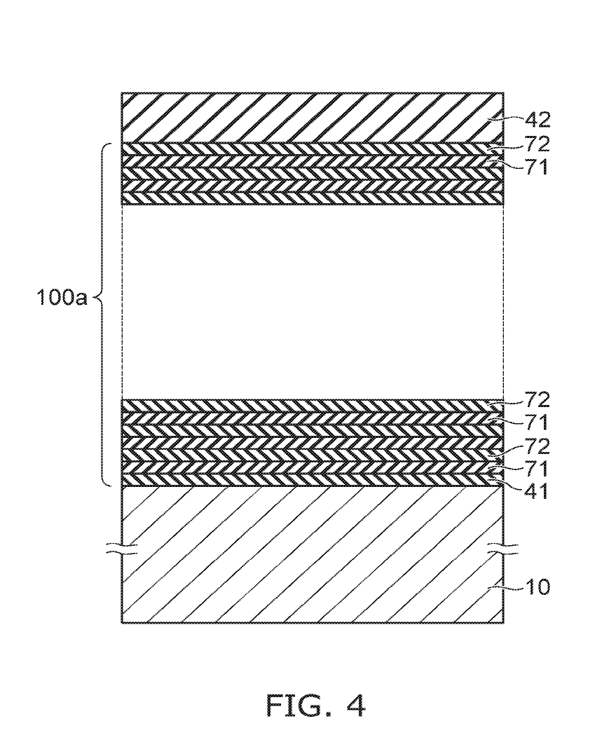

Then, a method of manufacturing the semiconductor device according to the embodiment will be described with reference to FIG. 4 through FIG. 21.

As shown in FIG. 4, the insulating layer 41 is formed on the substrate 10. Sacrifice layers 71 as first layers and the insulating layers 72 as second layers alternately are stacked on the insulating layer 41. The process of alternately stacking the sacrifice layers 71 and the insulating layers 72 is repeated to form the first stacked part 100a having a plurality of sacrifice layers 71 and a plurality of insulating layers 72 on the substrate 10.

The intermediate layer 42 is formed on the first stacked part 100a. The thickness of the intermediate layer 42 is thicker than the thickness of one of the sacrifice layers 71 and the thickness of one of the insulating layers 72.

For example, the sacrifice layers 71 are each a silicon nitride layer, and the insulating layers 72 and the intermediate layer 42 are each a silicon oxide layer.

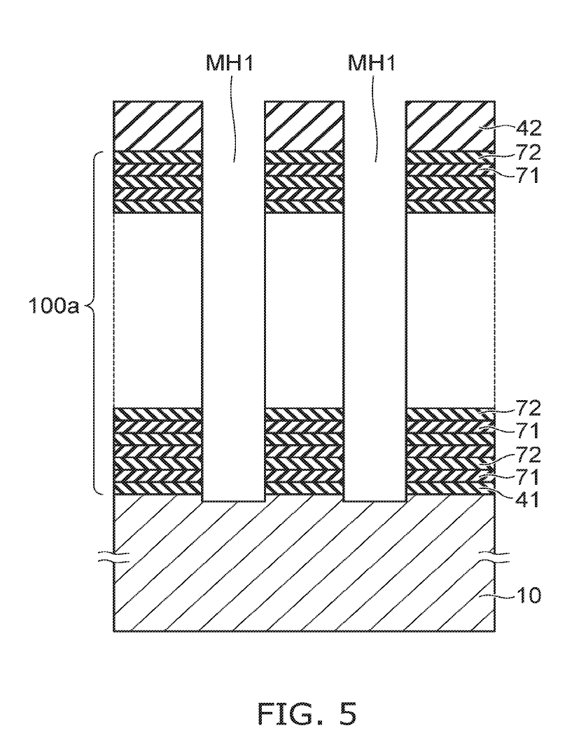

As shown in FIG. 5, a plurality of first memory holes MH1 is formed through the intermediate layer 42 and the first stacked part 100a. The first memory holes MH1 are formed by a reactive ion etching (RIE) method using a mask layer not shown. The first memory holes MH1 penetrate the intermediate layer 42 and the first stacked part 100a to reach the substrate 10.

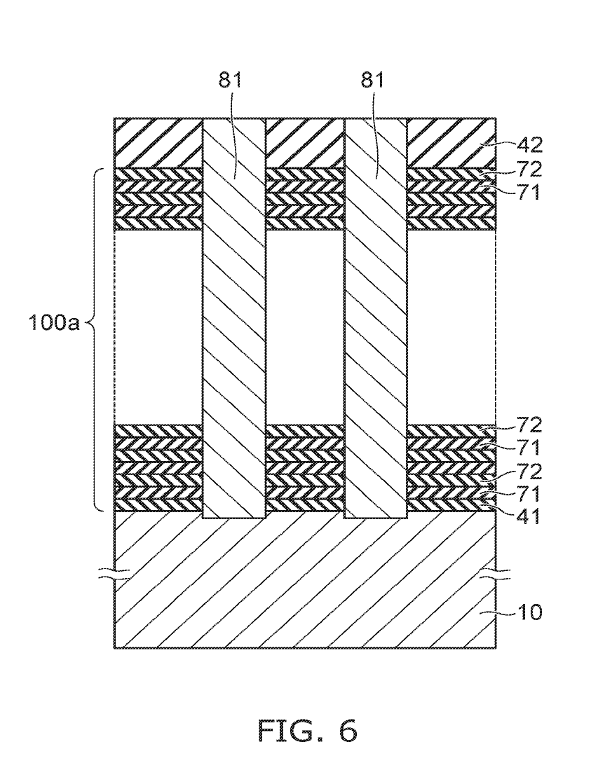

As shown in FIG. 6, sacrifice layers 81 are formed in the respective first memory holes MH1. The sacrifice layers 81 are respectively embedded in the first memory holes MH1. The sacrifice layers 81 are each a layer different in material from the intermediate layer 42 and the first stacked part 100a, and are each, for example, an amorphous silicon layer.

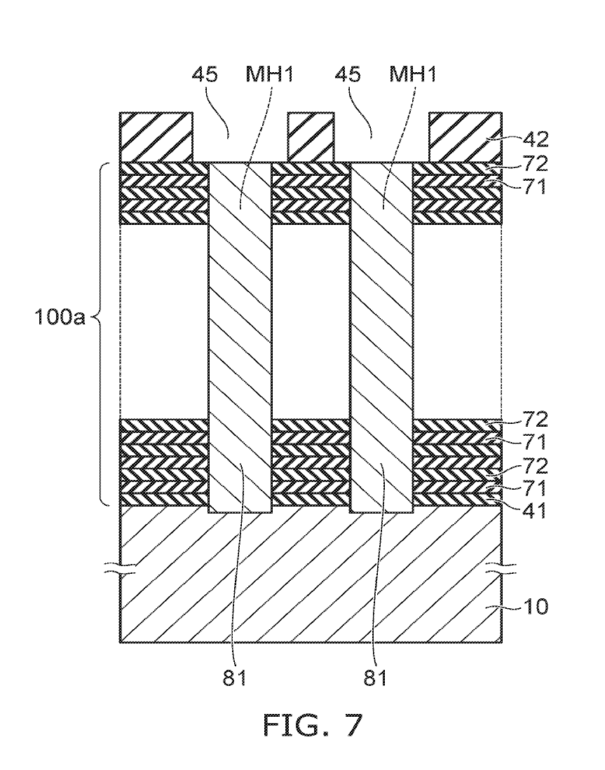

The upper surface of each of the sacrifice layers 81 is made to recede to the first stacked part 100a using, for example, a wet method, and then the diameter of a part (a joint region 45) of each of the first memory holes MH1 surrounded by the intermediate layer 42 is increased as shown in FIG. 7. Using, for example, a wet method, the diameter of the joint region 45 is made larger than the diameter of the first memory hole MH1.

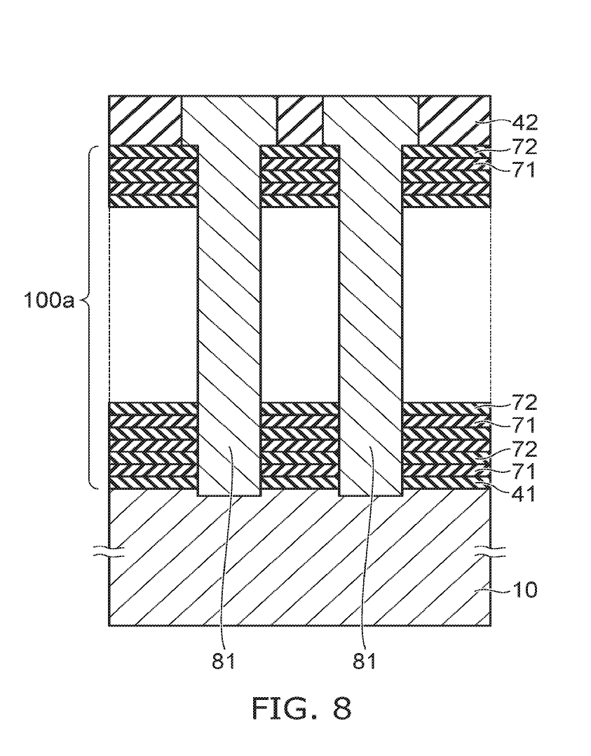

As shown in FIG. 8, the sacrifice layers 81 are embedded again in the respective joint regions 45 with the diameter increased.

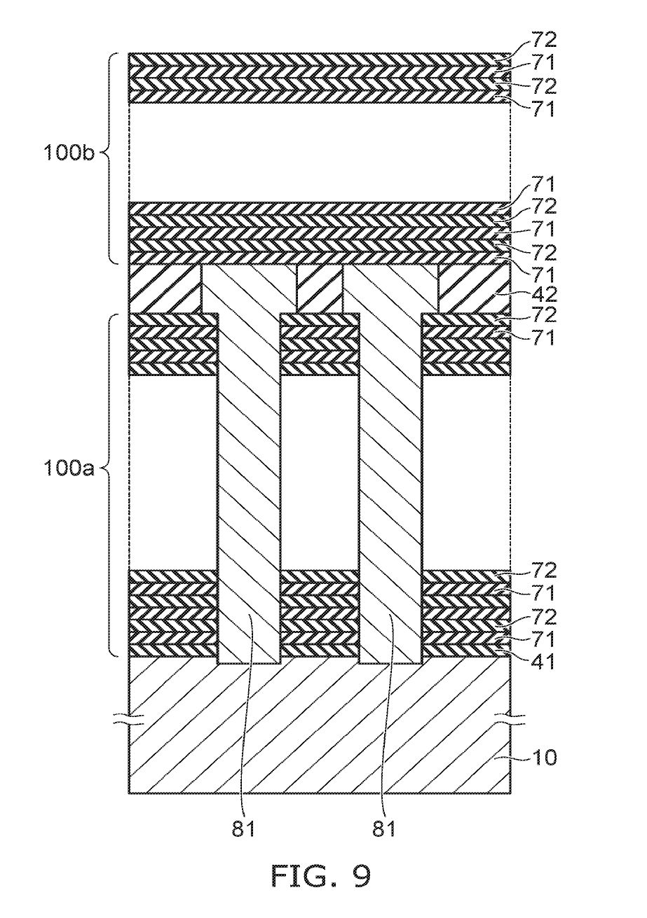

As shown in FIG. 9, sacrifice layers 71 as third layers and the insulating layers 72 as fourth layers alternately are stacked on the intermediate layer 42 and the sacrifice layers 81. The process of alternately stacking the sacrifice layers 71 and the insulating layers 72 is repeated to form the second stacked part 100b having a plurality of sacrifice layers 71 and a plurality of insulating layers 72 on the intermediate layer 42 and the sacrifice layers 81.

Similarly to the first stacked part 100a, the sacrifice layers 71 of the second stacked part 100b are each a silicon nitride layer, and the insulating layers 72 are each a silicon oxide layer.

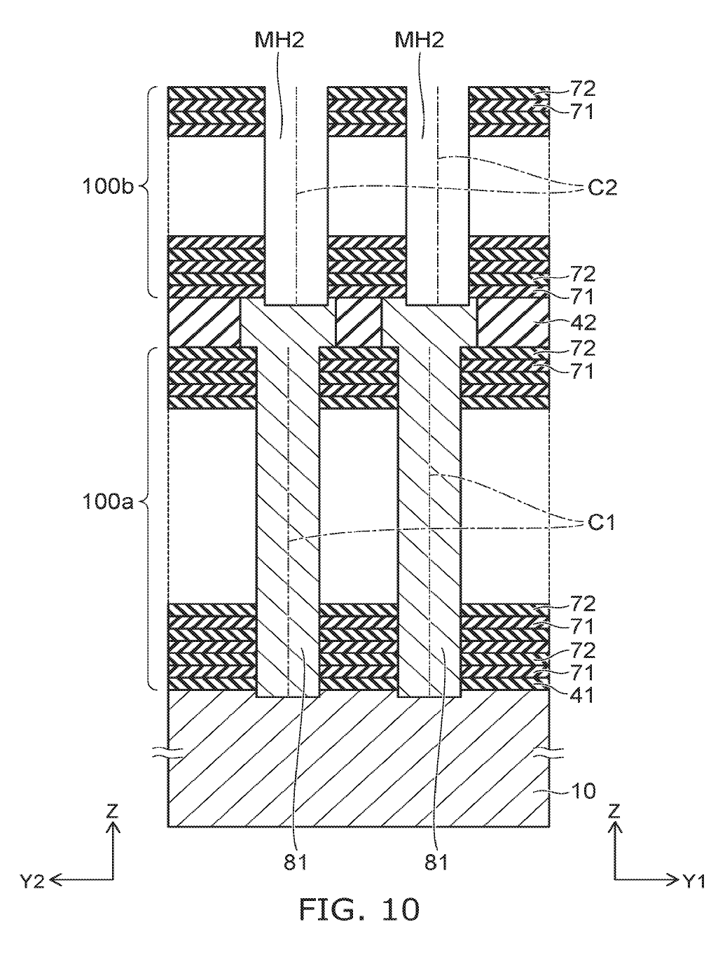

As shown in FIG. 10, a plurality of second memory holes MH2 is formed through the second stacked part 100b. The second memory holes MH2 are formed by the RIE method using a mask layer not shown. The second memory holes MH2 penetrate the second stacked part 100b to reach the respective sacrifice layers 81 embedded in the intermediate layer 42.

FIG. 10 shows the state in which the second memory holes MH2 are shifted in the Y1-direction with respect to the respective first memory holes MH1. The central axes C2 of the respective second memory holes MH2 are shifted in the Y1-direction with respect to the central axes C1 of the respective first memory holes MH1, respectively.

The sacrifice layers 81 function as etching stoppers in the RIE of the second memory holes MH2, respectively. The diameter of each of the sacrifice layers 81 embedded in the intermediate layer 42 is larger than the diameter of each of the second memory holes MH2. Therefore, the bottom of each of the second memory holes MH2 does not run off the sacrifice layer 81, and it is possible to surely stop etching by the sacrifice layer 81. It is possible to prevent the intermediate layer 42 and the first stacked part 100a below the intermediate layer 42 from being etched.

After forming the second memory holes MH2, the intermediate layer 42 and the sacrifice layers 81 embedded in the first memory holes MH1 are removed. For example, the sacrifice layers 81 as the amorphous silicon layers are removed by the wet method.

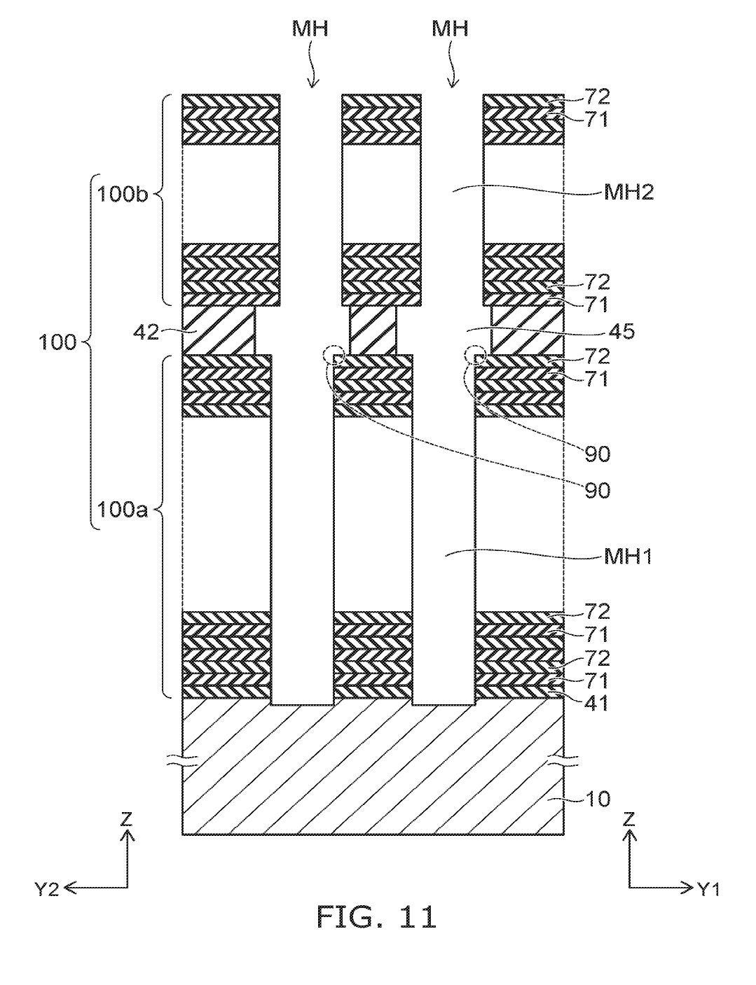

As shown in FIG. 11, the second memory holes MH2, the joint regions 45, and the first memory holes MH1 are respectively connected to each other to form the memory holes MH in the stacked body 100.

In each of the memory holes MH, a step part (a corner part or a shoulder part) between the side surface on the Y1-direction side of the joint region 45 and the side surface on the Y1-direction side of the first memory hole MH1 is exposed. The step part 90 is exposed at a position vertically overlapping the second memory hole MH2.

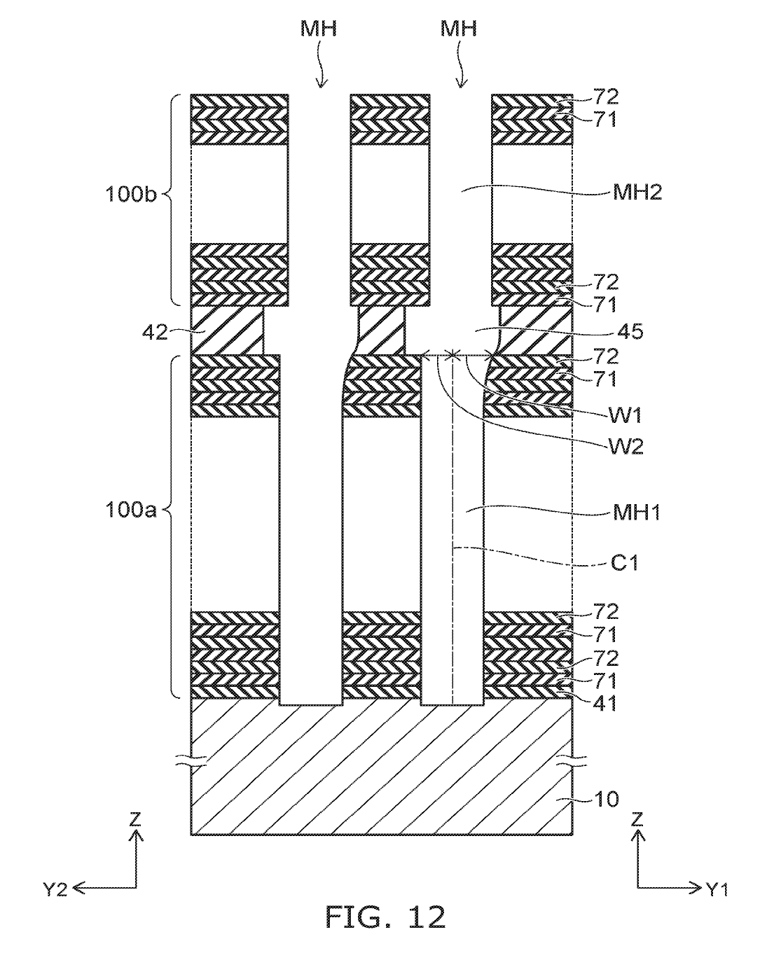

Then, the step parts 90 are etched by the RIE method to reduce the curvature factor of the corner of each of the step parts 90 as shown in FIG. 12.

Due to the etching process of the step parts 90, the upper end width of each of the first memory holes MH1 is locally enlarged while being biased toward the Y1-direction side. The width W1 along the Y1-direction from the central axis C1 of the first memory hole MH1 in the upper end of the first memory hole MH1 becomes larger than the width W2 along the Y2-direction from the central axis C1 of the first memory hole MH1 in the upper end of the first memory hole MH1.

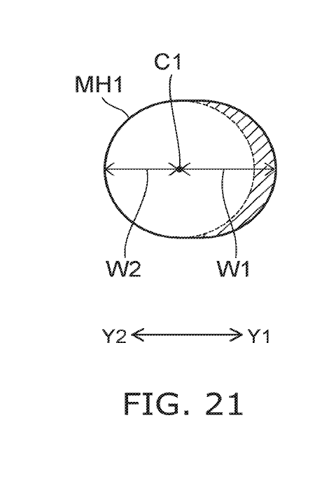

FIG. 21 is a schematic plan view of the upper end of the first memory hole MH1. The area indicated by hatching on the Y1-direction side from the central axis C1 is the area enlarged from the dotted line position before etching of the step part 90 toward the Y1-direction.

The step between the side surface on the Y1-direction side of the joint region 45 and the side surface on the Y1-direction side of the first memory hole MH1 becomes smaller than the step between the side surface on the Y2-direction side of the joint region 45 and the side surface on the Y2-direction side of the first memory hole MH1.

The side surface on the Y1-direction side of the joint region 45 and the side surface on the Y1-direction side of the first memory hole MH1 are connected to each other more gently than the connection between the side surface on the Y2-direction side of the joint region 45 and the side surface on the Y2-direction side of the first memory hole MH1.

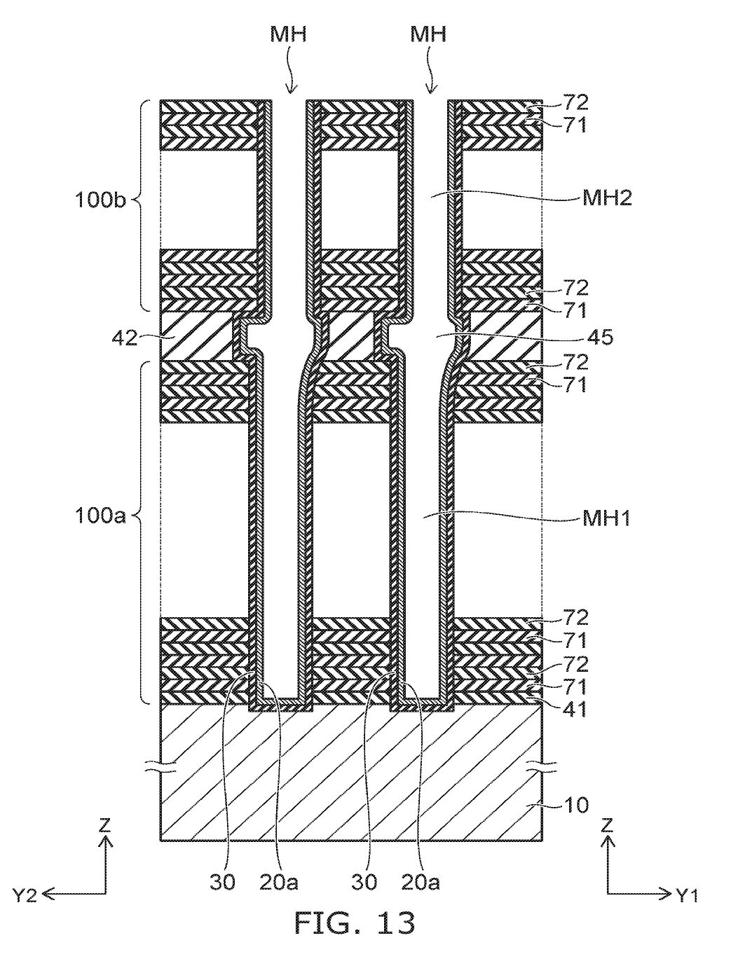

As shown in FIG. 13, the memory film 30 is formed in each of the memory holes MH. The memory film 30 is conformally formed along the side surface and the bottom of each of the memory holes MH. The block film 33, the charge storage film 32, and the tunnel insulating film 31 shown in FIGS. 3A and 3B are formed in sequence in each of the memory holes MH.

A cover film 20a is formed on the inner side of the memory film 30. The cover film 20a is conformally formed along the side surface and the bottom of each of the memory holes MH.

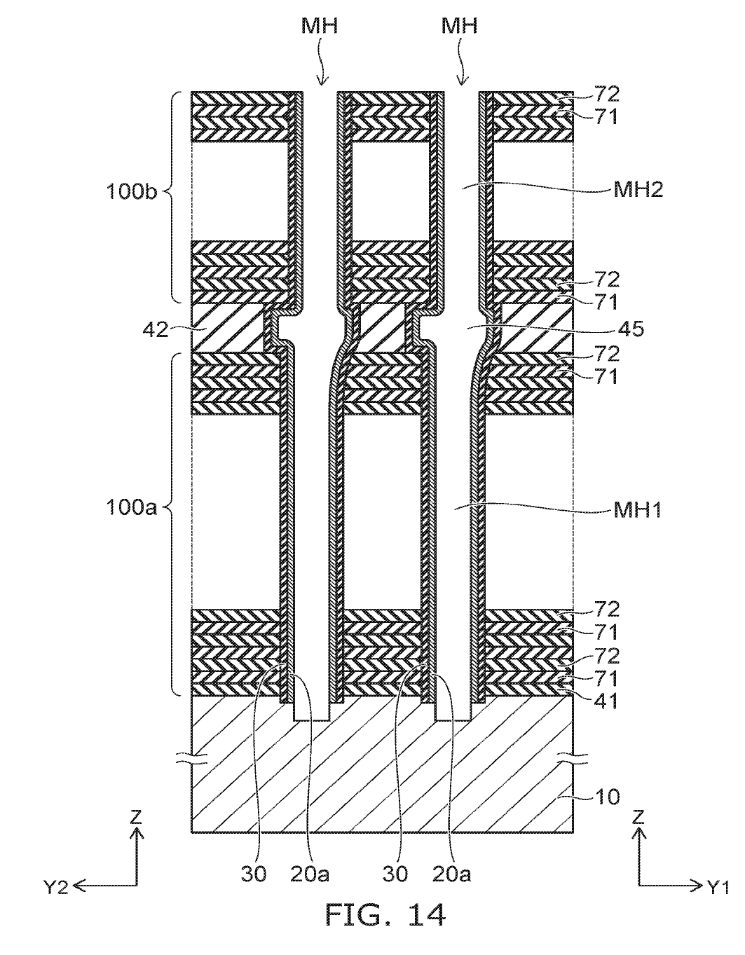

Then, as shown in FIG. 14, by the RIE method using a mask layer not shown, the cover film 20a and the memory film 30 deposited on the bottom of each of the memory holes MH are removed. During the RIE, the memory film 30 formed on the side surface of each of the memory holes MH is covered with the cover film 20a to thereby be protected, and is not damaged by the RIE.

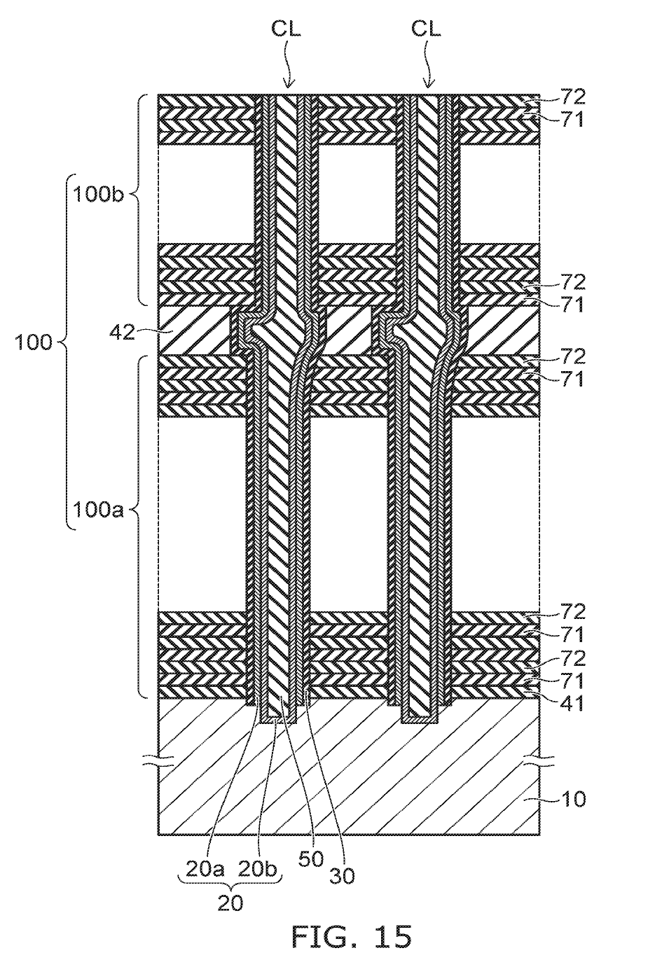

Subsequently, as shown in FIG. 15, a body film 20b is formed in each of the memory holes MH. The body film 20b is formed on the side surface of the cover film 20a, and the substrate 10 exposed on the bottom of the memory hole MH. The lower end part of each of the body films 20b has contact with the substrate 10.

The cover film 20a and the body film 20b are each formed as, for example, an amorphous silicon film, and are then crystallized by a thermal treatment into polycrystalline silicon films to constitute the semiconductor body 20 described above.

The core film 50 is formed on the inner side of each of the body films 20b. In such a manner as described above, the plurality of columnar portions CL each including the memory film 30, the semiconductor body 20, and the core film 50 is formed in the stacked body 100.

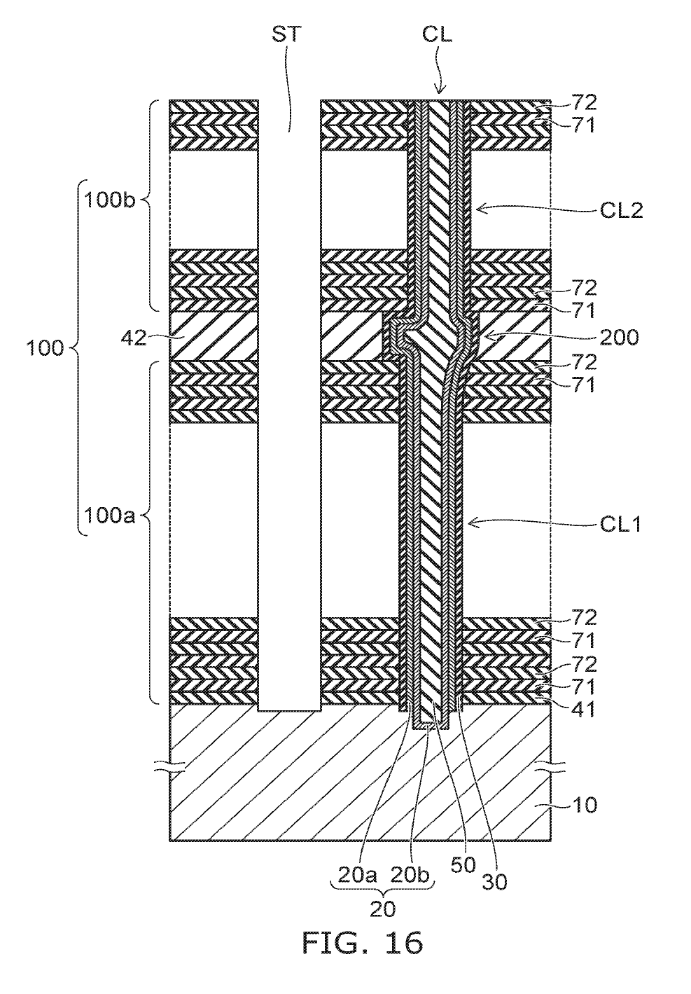

Subsequently, by the RIE method using a mask layer not shown, the plurality of slits ST is formed in the stacked body 100 as shown in FIG. 16. The slits ST each penetrate the stacked body 100 to reach the substrate 10.

Then, the sacrifice layers 71 are removed using an etching solution or an etching gas supplied through the slits ST. For example, the sacrifice layers 71 as silicon nitride layers are removed using an etching solution including a phosphoric acid.

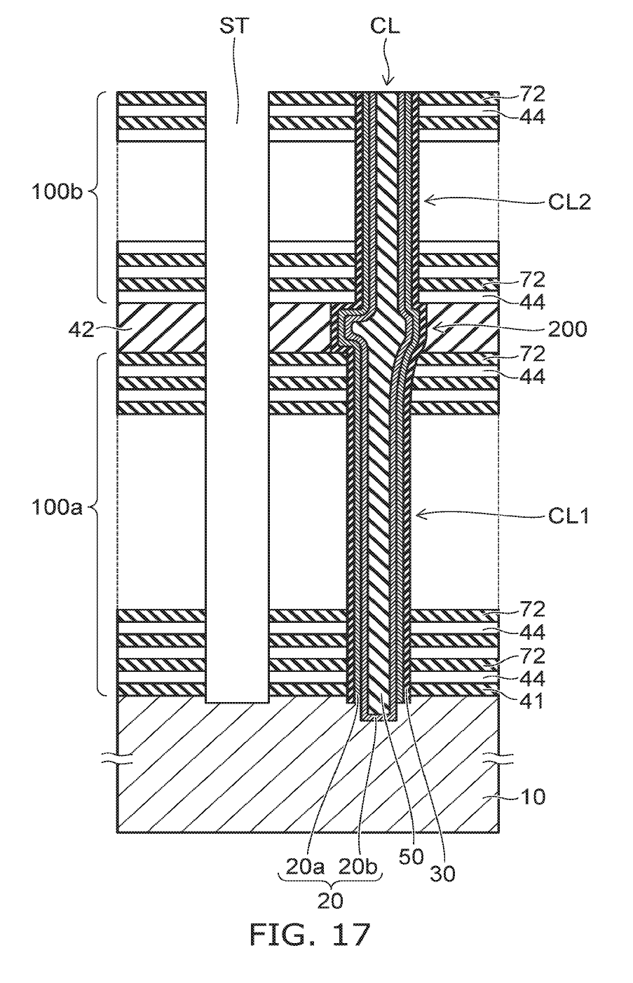

The sacrifice layers 71 are removed, and gaps 44 are formed between the insulating layers 72 vertically adjacent to each other as shown in FIG. 17. The gap 44 is also formed between the insulating layer 41 and the lowermost one of the insulating layers 72.

The plurality of insulating layers 72 of the stacked body 100 have contact with the side surface of each of the columnar portions CL so as to surround the side surface of each of the columnar portions CL. The plurality of insulating layers 72 is supported by physical bonding to such a plurality of columnar portions CL to keep the gaps 44 between the insulating layers 72.

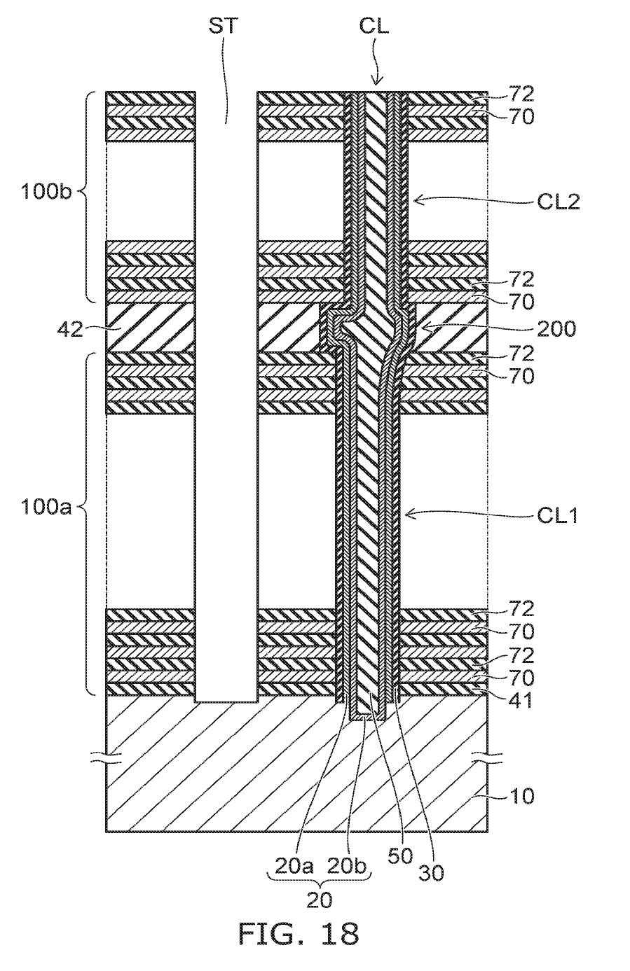

As shown in FIG. 18, the electrode layers 70 are formed in the gaps 44. The electrode layers 70 are formed by, for example, a CVD (chemical vapor deposition) method. The source gas is supplied to the gaps 44 through the slits ST. The electrode layer 70 formed on the side surface of each of the slits ST is removed.

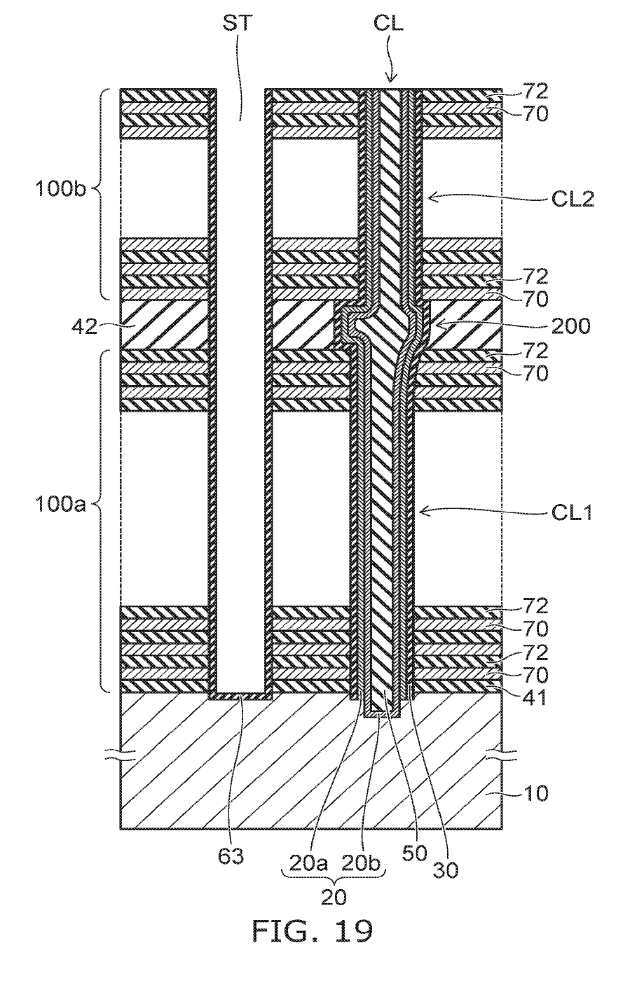

Subsequently, as shown in FIG. 19, an insulating film 63 is formed on the side surface and the bottom of each of the slits ST. The insulating film 63 formed on the bottom of each of the slits ST is removed by the RIE method, and then, the interconnect portion LI is embedded in the inner side of the insulating film 63 in the slit ST as shown in FIG. 20. The lower end of the interconnect portion LI has contact with the substrate 10.

According to the embodiment described hereinabove, the step parts (the corner parts or the shoulder parts) 90 shown in FIG. 11 are made gentle as shown in FIG. 12, and then the memory films 30 shown in FIG. 13 are formed.

Then, as shown in FIG. 14, when removing the memory film 30 on the bottom of each of the memory holes MH, since the memory film 30 does not project in the Y2-direction in the connection part between the joint region 45 and the first memory hole MH1, etching of the memory film 30 in the connection part can be prevented.

This prevents the degradation in characteristics of the memory film 30. Further, it is possible to prevent short circuit between the electrode layer 70 and the semiconductor body 20 due to local disappearance of the memory film 30.

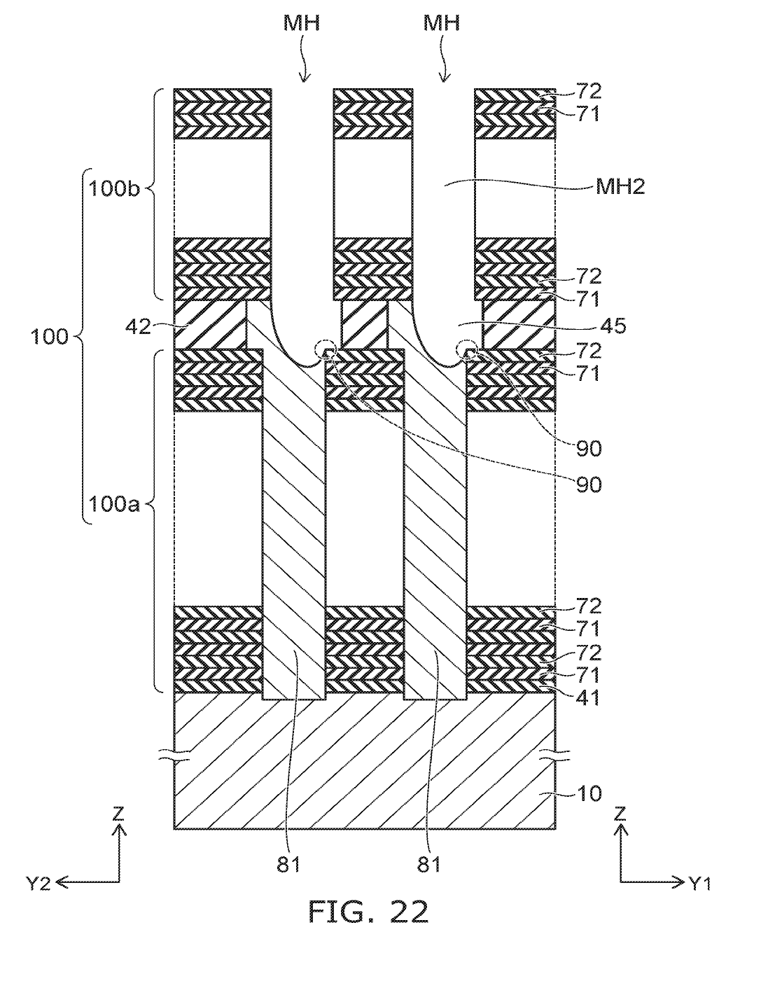

After the process shown in FIG. 10, it is also possible to expose the step parts 90 by partial etching (RIE) of the sacrifice layer 81 as shown in FIG. 22.

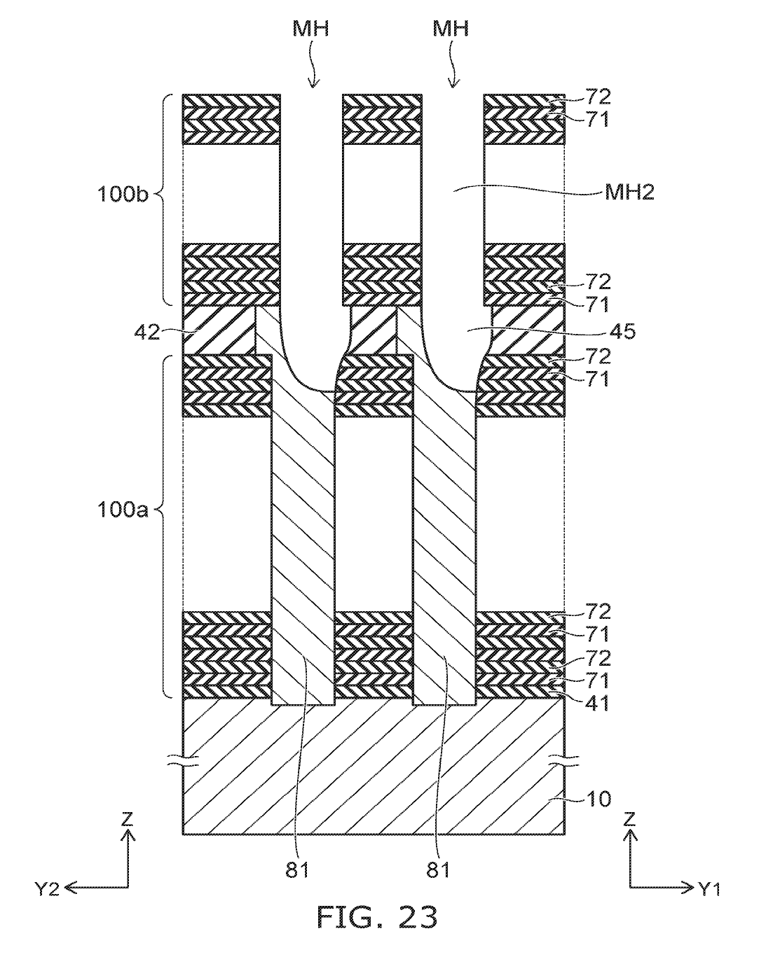

Then, the step parts 90 are etched in the state in which the sacrifice layer 81 is embedded in each of the first memory holes MH1 to make the joint region 45 and the first memory hole MH1 be connected gently to each other as shown in FIG. 23. Subsequently, the sacrifice layers 81 are removed, and the process shown in FIG. 12 and the subsequent drawings is continued.

Since the step parts 90 are etched in the state in which the sacrifice layer 81 is left in each of the first memory holes MH1, it is possible to prevent excessive etching of the area immediately below the step part 90 in the first stacked part 100a. It is possible to prevent unwanted expansion of the diameter of the first memory holes MH1.

The formation of the first memory holes MH1 and the second memory holes MH2, the etching of the step parts 90, the removal of the cover film 20a and the memory film 30 on the bottom of each of the memory holes MH, and the removal of part of the sacrifice layers 81 shown in FIG. 22 are performed with the RIE method using a gaseous species providing an appropriate selection ratio between the etching target and the non-etching target.

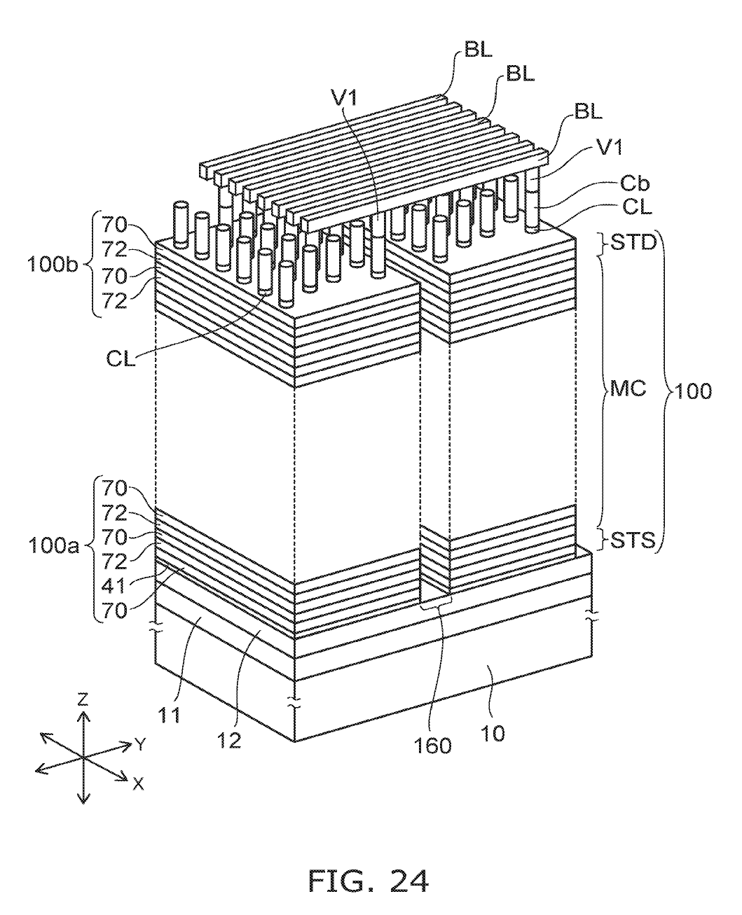

FIG. 24 is a schematic perspective view of another example of the memory cell array according to the embodiment. A first foundation layer 11 and a second foundation layer 12 are provided between the substrate 10 and the first stacked part 100a. The first foundation layer 11 is provided between the substrate 10 and the second foundation layer 12, and the second foundation layer 12 is provided between the first foundation layer 11 and the first stacked part 100a.

The second foundation layer 12 is a semiconductor layer or an electrically conductive layer. Alternatively, the second foundation layer 12 can include a stacked film of the semiconductor layer and the electrically conductive layer. The first foundation layer 11 includes a transistor and an interconnect constituting the control circuit.

The lower end of the semiconductor body 20 of the first columnar part CL1 has contact with the second foundation layer 12, and the second foundation layer 12 is connected to the control circuit. Therefore, the lower end of the semiconductor body 20 of the first columnar part CL1 is electrically connected to the control circuit via the second foundation layer 12. Therefore, the second foundation layer 12 can be used as a source layer.

The stacked body 100 is separated by the separation portions 160 in the Y-direction into a plurality of blocks (or finger parts) 200. The separation portions 160 are each an insulating film, and do not include wiring.

Although in the embodiment described above, the silicon nitride layers are illustrated as the first layers 71, it is also possible to use metal layers or silicon layers doped with impurities as the first layers 71. In this case, since the first layers 71 directly function as the electrode layers 70, the process of replacing the first layers 71 with the electrode layers is unnecessary.

Further, it is also possible to remove the second layers 72 with etching through the slits ST to form air gaps between the electrode layers 70 vertically adjacent to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a foundation layer;
a first stacked part provided on the foundation layer, the first stacked part including a plurality of first electrode layers stacked with first insulators interposed;
a first columnar part including a first semiconductor body extending in the first stacked part in a stacking direction of the first stacked part, and a first charge storage part provided between the first semiconductor body and one of the first electrode layers;
a second stacked part provided on the first stacked part, the second stacked part including a plurality of second electrode layers stacked with second insulators interposed;
a second columnar part including a second semiconductor body extending in the second stacked part in a stacking direction of the second stacked part, and a second charge storage part provided between the second semiconductor body and one of the second electrode layers;
an intermediate layer provided between the first stacked part and the second stacked part; and
a joint part provided between the first columnar part and the second columnar part in the intermediate layer, and having a diameter larger than a diameter of the first columnar part and a diameter of the second columnar part, and including an intermediate semiconductor body continuous with the first semiconductor body and the second semiconductor body,
a central axis of the second columnar part being shifted in a first direction along a surface of the foundation layer with respect to a central axis of the first columnar part, and
a width along the first direction from the central axis of the first columnar part in an upper end of the first columnar part being larger than a width along a second direction opposite to the first direction from the central axis of the first columnar part in the upper end of the first columnar part.

2. The device according to claim 1, wherein
a step between a sidewall on the first direction side of the joint part and a sidewall on the first direction side of the first columnar part is smaller than a step between a sidewall on the second direction side of the joint part and a sidewall on the second direction side of the first columnar part.

3. The device according to claim 1, wherein
a displacement toward the second direction of the sidewall on the second direction side of the joint part from a sidewall on the second direction side of the second columnar part is larger than a displacement toward the second direction of the sidewall on the second direction side of the joint part from the sidewall on the second direction side of the first columnar part.

4. The device according to claim 1, wherein
the intermediate layer is thicker than a thickness of one layer of the first electrode layers and a thickness of one layer of the second electrode layers.

5. The device according to claim 1, wherein
the intermediate layer is an insulating layer.

6. The device according to claim 1, wherein
the first insulator, the second insulator, and the intermediate layer are layers made of a same material.

7. The device according to claim 1, wherein
the first charge storage part extends in the stacking direction of the first stacked part, and the second charge storage part extends in the stacking direction of the second stacked part, and
the joint part has a film continuous with the first charge storage part and the second charge storage part.

8. The device according to claim 1, wherein
the foundation layer has an electrically conductive property, and
the first semiconductor body has contact with the foundation layer.

9. The device according to claim 8, wherein
the foundation layer has a semiconductor region doped with an impurity, and
the first semiconductor body has contact with the semiconductor region.

10. A method of manufacturing a semiconductor device, comprising:
forming a first stacked part on a foundation layer, the first stacked part including a plurality of first layers and a plurality of second layers, the first layers and the second layers including a first layer and a second layer stacked alternately;
forming an intermediate layer on the first stacked part;
forming a first hole in the intermediate layer and the first stacked part;
increasing a diameter of a joint region surrounded by the intermediate layer in the first hole;
forming a sacrifice layer in the first hole including the joint region with the diameter increased;
forming a second stacked part on the intermediate layer and the sacrifice layer, the second stacked part including a plurality of third layers and a plurality of fourth layers, the third layers and the fourth layers including a third layer and a fourth layer stacked alternately;
forming a second hole reaching the sacrifice layer in the second stacked part, a central axis of the second hole being shifted in a first direction along a surface of the foundation layer with respect to a central axis of the first hole;
removing at least a part of the sacrifice layer to expose a step part between a side surface on the first direction side in the joint region and a side surface on the first direction side in the first hole;
etching the step part; and
forming a columnar part in the first hole, the joint region, and the second hole after etching the step part.

11. The method according to claim 10, wherein
the forming the columnar part includes
forming an insulating film on a bottom of the first hole, a side surface of the first hole, a side surface of the joint region, and a side surface of the second hole,
removing the insulating film on the bottom of the first hole to expose the foundation layer on the bottom of the first hole, and
forming a semiconductor body on a side surface of the insulating film, and the foundation layer exposed on the bottom of the first hole.

12. The method according to claim 11, wherein
the etching of the step part and the etching of the insulating film on the bottom of the first hole are performed with an RIE (reactive ion etching) using a same gas.

13. The method according to claim 10, wherein
the step part is exposed in a state of leaving the sacrifice layer in the first hole, and then the step part is etched.

14. The method according to claim 10, wherein
a diameter of the joint region is increased in a state of leaving the sacrifice layer in the first hole.

15. The method according to claim 10, wherein
the first layer and the third layer are layers made of a same material, and the second layer and the fourth layer are layers made of a same material.

16. The method according to claim 10, wherein
the intermediate layer, the second layer, and the fourth layer are layers made of a same material.

17. The method according to claim 10, wherein
the first layer and the third layer are each a silicon nitride layer, and
the intermediate layer, the second layer and the fourth layer are each a silicon oxide layer.

18. The method according to claim 17, further comprising:
replacing the first layer and the third layer with electrode layers after forming the columnar part.

19. The method according to claim 17, wherein
the sacrifice layer is a silicon layer.

20. The method according to claim 10, wherein
the intermediate layer is thicker than the first layer, the second layer, the third layer, and the fourth layer.
